(19) United States
(12) Patent Application Publication
(10) Pub. No.: US 2024/0113096 A1
(43) Pub. Date: Apr. 4, 2024

(54) DIELECTRIC FILMS OVER ELECTRODE FOR HIGH VOLTAGE PERFORMANCE

(71) Applicant: Texas Instruments Incorporated, Dallas, TX (US)

(72) Inventors: Jeffrey Alan West, Dallas, TX (US); Yoshihiro Takei, USHIKU (JP); Mitsuhiro Sugimoto, TSUKUBA (JP)

(21) Appl. No.: 18/149,099

(22) Filed: Dec. 31, 2022

Related U.S. Application Data
(60) Provisional application No. 63/411,961, filed on Sep. 30, 2022.

(51) Int. Cl. H01L 27/01

(52) U.S. Cl. CPC H01L 27/016

(57) ABSTRACT

A microelectronic device includes a lower isolation element and an upper isolation element, separated by an isolation dielectric layer stack. The microelectronic device includes a lower field reduction layer over the lower isolation element, under the isolation dielectric layer stack. The lower field reduction layer includes a first dielectric layer adjacent to the isolation dielectric layer stack, and a second dielectric layer over the first dielectric layer. A dielectric constant of the first dielectric layer is greater than a dielectric constant of the second dielectric layer. The dielectric constant of the second dielectric layer is greater than a dielectric constant of the isolation dielectric layer stack adjacent to the lower field reduction layer. Methods of forming example microelectronic device having lower field reduction layers are disclosed.

### CROSS-REFERENCE TO RELATED APPLICATIONS

This application claims the benefit of priority under 35 U.S.C. § 119(e) of U.S. Provisional Application No. 63/411,961 (Texas Instruments docket number T102233US01), filed Sep. 30, 2022, which is hereby incorporated by reference in its entirety.

### TECHNICAL FIELD

This disclosure relates to the field of microelectronic devices. More particularly, but not exclusively, this disclosure relates to high voltage components in microelectronic devices.

### BACKGROUND

Microelectronic devices having high voltage components may electrically isolate conductive elements with one or more dielectric layers. Electric fields may be strongest at corners of the conductive elements, causing reliability issues such as trapped charge and dielectric breakdown.

### SUMMARY

The present disclosure introduces a microelectronic device including a lower isolation element above a substrate, and a lower field reduction layer over the lower isolation element. The lower field reduction layer includes a first dielectric layer adjacent to the isolation dielectric layer stack, and a second dielectric layer over the first dielectric layer. The microelectronic device includes an isolation dielectric layer stack over the lower field reduction layer, and an upper isolation element over the isolation dielectric layer stack. The first dielectric layer has a dielectric constant that is greater than a dielectric constant of the second dielectric layer. The dielectric constant of the second dielectric layer is greater than a dielectric constant of the isolation dielectric layer stack adjacent to the lower field reduction layer. Methods of forming example microelectronic devices having lower field reduction layers are disclosed.

### BRIEF DESCRIPTION OF THE VIEWS OF THE DRAWINGS

FIG. 1A through FIG. 1I are cross sections of an example microelectronic device having a lower field reduction layer, depicted in stages of an example method of formation.

FIG. 2A through FIG. 2G are cross sections of another example microelectronic device having a lower field reduction layer, depicted in stages of another example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

The following co-pending patent applications have related subject matter and are hereby incorporated by reference: U.S. patent application Ser. No. 17/957,847 (Texas Instruments docket number T102472US01, titled “GALVANIC ISOLATION DEVICE”, by West, et al.), Filed Sep. 9, 2022, and U.S. patent application Ser. No. 17/958,040 (Texas Instruments docket number T92886US01, titled “SINGLE DIE REINFORCED GALVANIC ISOLATION DEVICE”, by West, et al.), Filed Sep. 30, 2022. With their mention in this section, these patent applications are not admitted to be prior art with respect to the present invention.

A microelectronic device has a conductive substrate, such as a silicon substrate. The microelectronic device includes a lower isolation element above the substrate. The lower isolation element is electrically conductive. The lower isolation element may be manifested as a lower winding of an isolation transformer or magnetic isolator, or a lower plate of an isolation capacitor, by way of example. Other manifestation of the lower isolation element are within the scope of this disclosure.

The microelectronic device includes a lower field reduction layer over the lower isolation element. The lower field reduction layer includes at least a first dielectric layer adjacent to the lower isolation element, and at least a second dielectric layer over the first dielectric layer. The microelectronic device includes an isolation dielectric layer stack over the lower field reduction layer. The isolation dielectric layer stack may include one or more sublayers of dielectric material, such as silicon dioxide, silicon oxynitride, and silicon nitride.

An effective bandgap energy of the first dielectric layer is less than an effective bandgap energy of the second dielectric layer, and the effective bandgap energy of the second dielectric layer is less than an effective bandgap energy of the isolation dielectric layer stack adjacent to the lower field reduction layer. A dielectric constant of the first dielectric layer is greater than a dielectric constant of the second dielectric layer, and the dielectric constant of the second dielectric layer is greater than a dielectric constant of the isolation dielectric layer stack adjacent to the lower field reduction layer. A refractive index of the first dielectric layer is greater than a refractive index of the second dielectric layer, and the refractive index of the second dielectric layer is greater than a refractive index of the isolation dielectric layer stack adjacent to the lower field reduction layer. By way of example, the refractive index of the first dielectric layer may be 2.00 to 2.20.

For the purposes of this disclosure, the term “effective band gap energy” of a dielectric material refers to an energy difference between a top of a valence band of the dielectric material and a bottom of a conduction band of the dielectric material. The effective band gap energy of a layer of the dielectric material may be determined by ultraviolet reflection spectroscopy, at a photon energy at which reflection interference amplitude reduces to zero.

For the purposes of this disclosure, the term “dielectric constant” of a dielectric material refers to a ratio of the dielectric material's (absolute) electric permittivity to the vacuum electric permittivity, at a frequency below 1 hertz (Hz). The vacuum electric permittivity has a value of approximately 8.85×10⁻¹² farads/meter (F/m). The dielectric constant may be determined using atomic force microscopy (AFM).

For the purposes of this disclosure, the term “refractive index” of a dielectric material refers to a ratio of the speed of light in a vacuum to the speed of light in that material. The refractive index may be determined at visible wavelengths by ellipsometry.

The microelectronic device further includes an upper isolation element over the isolation dielectric layer stack. The upper isolation element may be manifested as an upper winding of the isolation transformer, a magnetic sensor of the magnetic isolator, or an upper plate of the isolation capacitor.

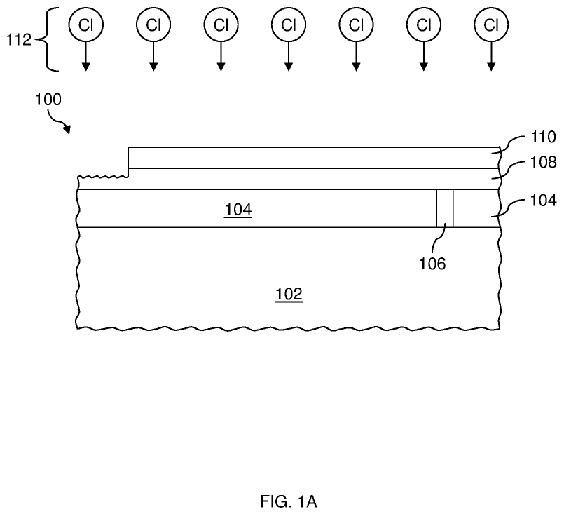

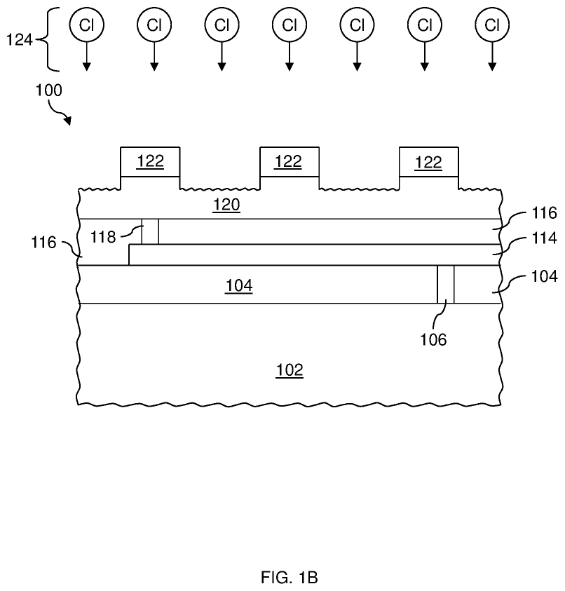

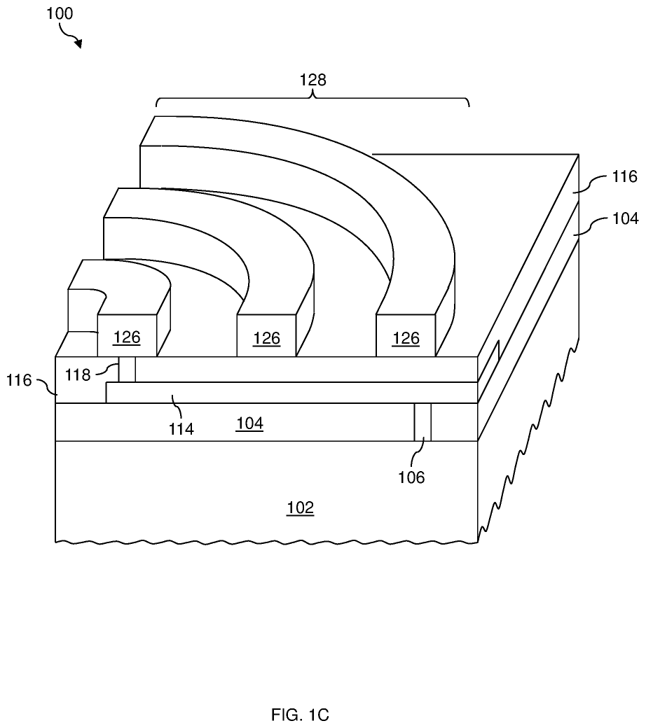

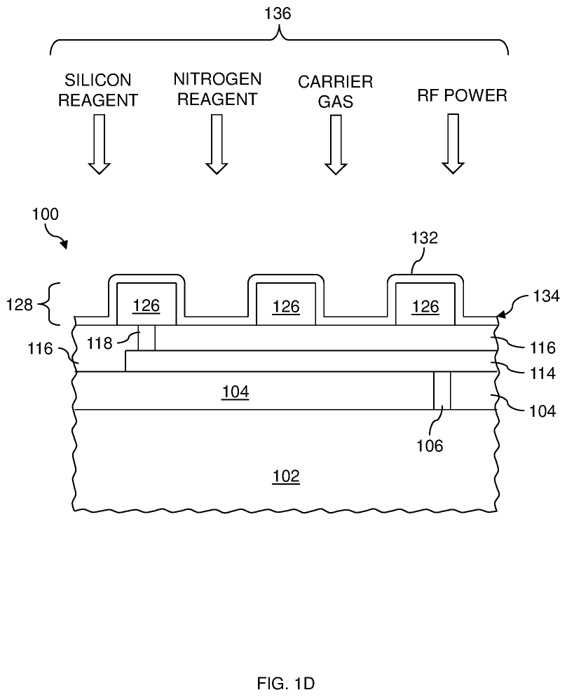

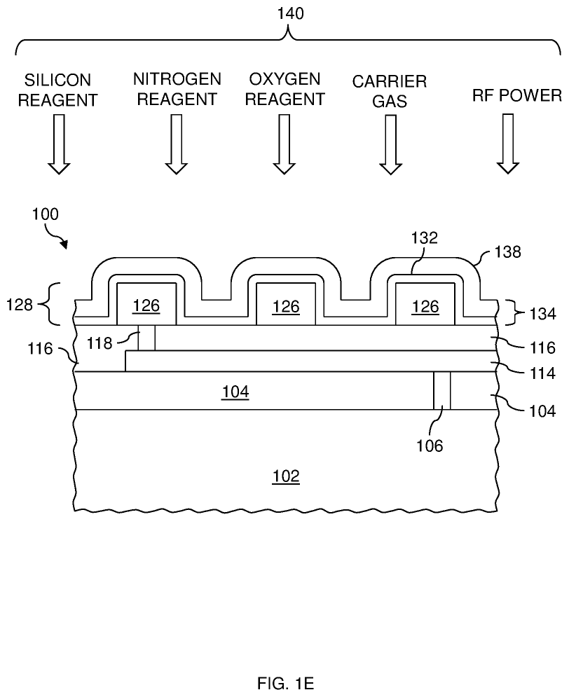

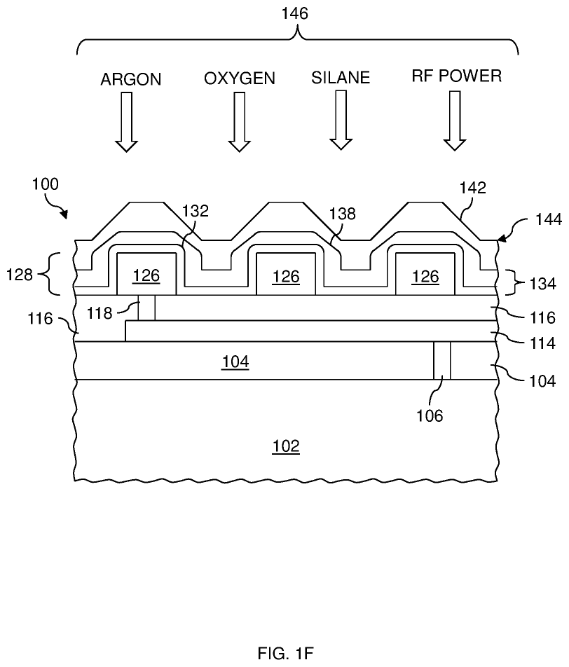

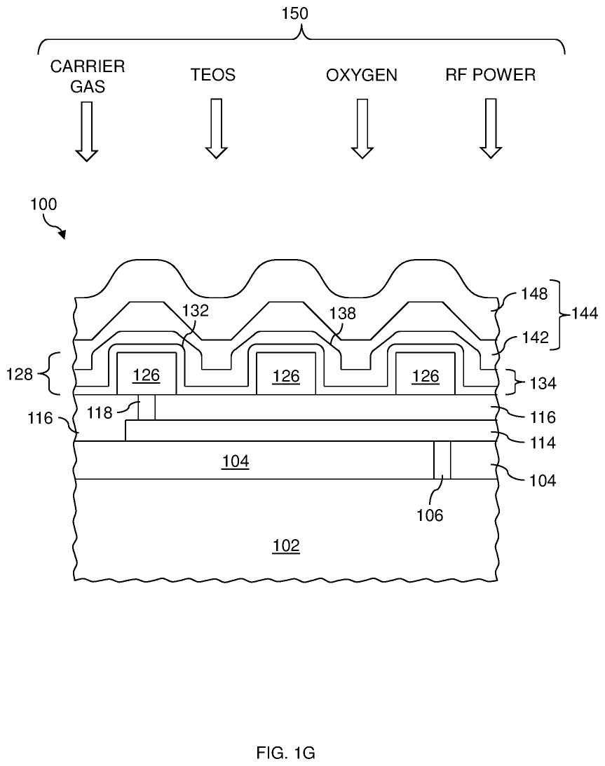

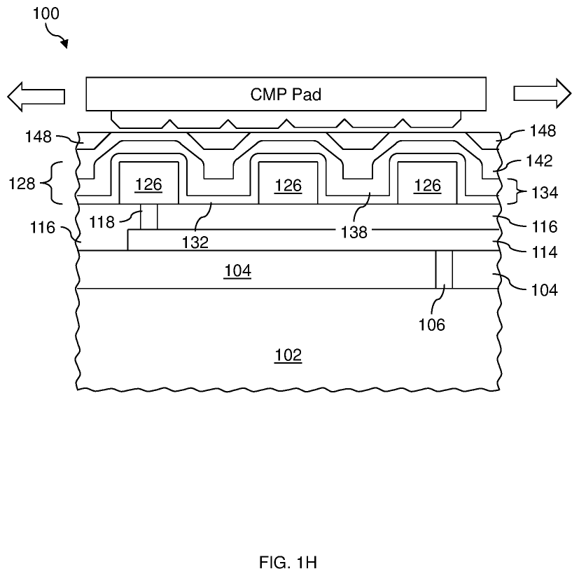

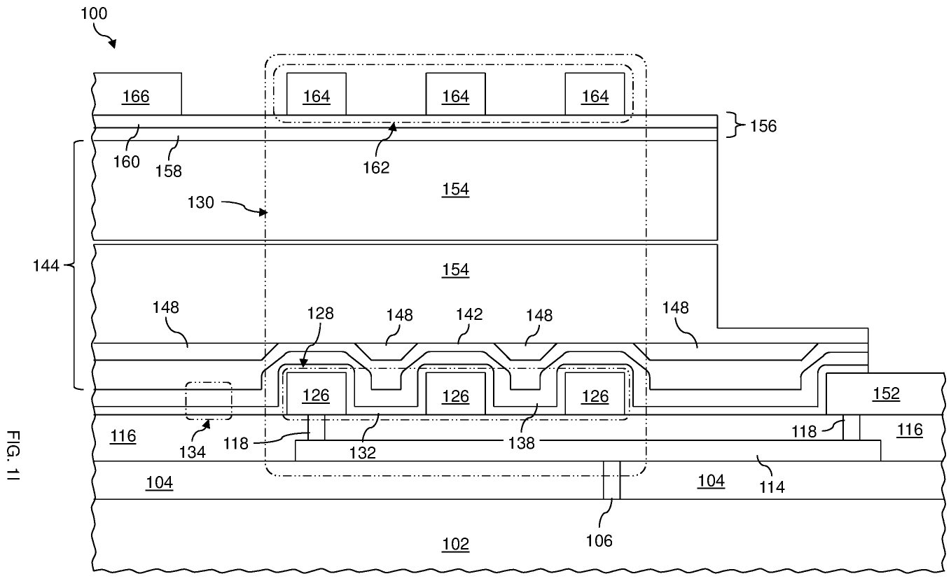

FIG. 1A through FIG. 1I are cross sections of an example microelectronic device having a lower field reduction layer, depicted in stages of an example method of formation. Referring to FIG. 1A, the microelectronic device 100 is formed on a substrate 102 which is electrically conductive. The substrate 102 may be implemented as a silicon wafer, for example. Other electrically conductive substrates, such as ceramic substrates with a conductive coating, are within the scope of this example.

A pre-metal dielectric (PMD) layer 104 is formed over the substrate 102. The PMD layer 104 may include one or more sublayers of dielectric material, such as a pad sublayer of thermal oxide, formed by a thermal oxidation process, on the substrate 102, an etch stop liner of silicon nitride, formed by a low pressure chemical vapor deposition (LPCVD) process, on the pad layer, a main sublayer of silicon dioxide, formed by a plasma enhanced chemical vapor deposition (PECVD) process, on the etch stop liner, and a chemical mechanical polish (CMP) stop sublayer of silicon carbide or silicon carbonitride, formed by a PECVD process or an LPCVD process, on the main sublayer. Other structures and compositions for the PMD layer 104 are within the scope of this example.

One or more contacts 106 may be formed through the PMD layer 104 to make electrical connection to the substrate 102. The contacts 106 are electrically conductive, and may include a contact liner, not shown, of titanium and titanium nitride contacting the PMD layer 104 and the substrate 102, with a tungsten core, not shown, on the contact liner. The contacts 106 may be formed by etching contact holes through the PMD layer 104 to expose the substrate 102. The contact liner may be formed by sputtering titanium followed by forming titanium nitride using an atomic layer deposition (ALD) process. The tungsten core may be formed by a metalorganic chemical vapor deposition (MOCVD) process using tungsten hexafluoride (WF6) reduced by silane initially and subsequently hydrogen. The tungsten, titanium nitride, and titanium are removed from a top surface of the PMD layer 104 by an etch process, a tungsten CMP process, or a combination of both, leaving the contacts 106 extending to the top surface of the PMD layer 104. Other structures and compositions for the contacts 106 are within the scope of this example.

A first interconnect metal stack 108 is formed over the PMD layer 104, making electrical connection to the contacts 106. The first interconnect metal stack 108 may include an adhesion sublayer of titanium or titanium tungsten, formed by a physical vapor deposition (PVD) process, on the PMD layer 104 and the contacts 106, a lower barrier sublayer of titanium nitride, formed by an ALD process or a reactive sputter process, on the adhesion sublayer, a main interconnect layer of aluminum with a few percent of chromium, copper, silicon, or other elements to reduce electromigration, formed by a PVD process, on the lower barrier sublayer, and an upper barrier sublayer of titanium nitride, formed by an ALD or reactive sputter process, on the main interconnect sublayer. Other sublayer structures and compositions for the first interconnect metal stack 108 are within the scope of this example.

A first interconnect etch mask 110 is formed over the first interconnect metal stack 108, covering the first interconnect metal stack 108 in areas for one or more subsequently formed first interconnects 114, shown in FIG. 1B. Referring back to FIG. 1A, the first interconnect etch mask 110 may include photoresist, formed by a photolithographic process, and may include anti-reflection material, such as a bottom anti-reflection coat (BARC).

A first aluminum reactive ion etch (RIE) process 112 is performed which produces chlorine radicals, as indicated schematically in FIG. 1A. The chlorine radicals remove the first interconnect metal stack 108 where exposed by the first interconnect etch mask 110, leaving the first interconnect metal stack 108 under the first interconnect etch mask 110 to form the first interconnects 114. FIG. 1A depicts the first aluminum RIE process 112 partway to completion.

After the first aluminum RIE process 112 is completed, the first interconnect etch mask 110 is removed. Organic material in the first interconnect etch mask 110, including photoresist and BARC, may be removed by exposure an oxygen plasma, such as an asher process, followed by a wet clean process.

Referring to FIG. 1B, an inter-level dielectric (ILD) layer 116 is formed over the PMD layer 104 and the first interconnects 114. The ILD layer 116 may include one or more sublayers of dielectric material, such as an etch stop sublayer of silicon nitride, formed by an LPCVD process, on the PMD layer 104 and the first interconnects 114, a main sublayer of silicon dioxide, formed by a PECVD process, on the etch stop sublayer, and a CMP stop sublayer of silicon carbide or silicon carbonitride, formed by a PECVD process or an LPCVD process, on the main sublayer. Other structures and compositions for the ILD layer 116 are within the scope of this example.

One or more vias 118 are formed through the ILD layer 116, making electrical connections to the first interconnects 114. The vias 118 may have a structure and a composition similar to the contacts 106, and may be formed by a similar process.

A second interconnect metal stack 120 is formed over the ILD layer 116, making electrical connection to the vias 118. The second interconnect metal stack 120 may have a sublayer structure and a composition similar to the first interconnect metal stack 108 of FIG. 1A. The second interconnect metal stack 120 may have a thicker main interconnect layer than the first interconnect metal stack 108, to carry a desired current through narrower interconnect lines.

A second interconnect etch mask 122 is formed over the second interconnect metal stack 120, covering the second interconnect metal stack 120 in areas for one or more subsequently formed second interconnects 126, shown in FIG. 1C. Referring back to FIG. 1B, the second interconnect etch mask 122 may have a composition and a structure similar to the first interconnect etch mask 110 of FIG. 1A.

A second aluminum RIE process 124 is performed which produces chlorine radicals, as indicated schematically in FIG. 1B. The chlorine radicals remove the second interconnect metal stack 120 where exposed by the second interconnect etch mask 122, leaving the second interconnect metal stack 120 under the second interconnect etch mask 122 to form the second interconnects 126. FIG. 1B depicts the second aluminum RIE process 124 partway to completion.

After the second aluminum RIE process 124 is completed, the second interconnect etch mask 122 is removed. The second interconnect etch mask 122 may be removed by a process similar to the process used to remove the first interconnect etch mask 110.

FIG. 1C depicts the microelectronic device 100 after the second interconnect etch mask 122 of FIG. 1B is removed. The second interconnects 126 provide a lower isolation element 128 of an isolation component 130, shown in FIG. 1I. The lower isolation element 128 may be manifested as a lower winding 128, in this example. The lower isolation element 128 has an etched aluminum configuration, in which the lower isolation element 128 includes primarily aluminum and is located on a planar dielectric surface.

Referring to FIG. 1D, a first dielectric layer 132 of a lower field reduction layer 134 is formed over the lower isolation element 128. The first dielectric layer 132 may be implemented as a conformal layer over the lower isolation element 128 and the ILD layer 116, in which a thickness of the first dielectric layer 132 on vertical surfaces of the lower isolation element 128 is at least half of a thickness of the first dielectric layer 132 on horizontal surfaces of the lower isolation element 128. The first dielectric layer 132 may include primarily silicon nitride. The first dielectric layer 132 may be 100 nanometers to 500 nanometers thick on horizontal surfaces of the lower isolation element 128. The first dielectric layer 132 of this example may have a refractive index of 2.03 to 2.07, a dielectric constant of 6.5 to 9.0, and an effective bandgap energy of 4.5 electron-volts (eV) to 5.3 eV, by way of example.

The first dielectric layer 132 may be formed by a first PECVD process 136 which provides a carrier gas, labeled “CARRIER GAS”, such as nitrogen, a silicon reagent gas, labeled “SILICON REAGENT”, such as silane or dichlorosilane, a nitrogen reagent gas, labeled “NITROGEN REAGENT”, such as ammonia, and radio-frequency (RF) power, labeled “RF POWER”, to sustain a plasma. Flow rates of the silicon reagent gas and the nitrogen reagent gas may be adjusted to attain a desired refractive index of the first dielectric layer 132. The refractive index of 2.03 to 2.07 and dielectric constant of 6.5 to 9.0 may be attained in the first PECVD process 136 by providing a silane flow rate of 900 standard cubic centimeters per minute (sccm) to 1200 sccm, an ammonia flow rate of 200 sccm to 300 sccm, and a carrier gas flow rate of 10,000 sccm to 12,000 sccm, at a pressure of 4 torr to 6 torr and an RF power of 900 watts to 1200 watts, for a 300 millimeter wafer. Other process conditions to attain the refractive index of 2.03 to 2.07 are within the scope of this example.

Referring to FIG. 1E, a second dielectric layer 138 of the lower field reduction layer 134 is formed over the first dielectric layer 132. The second dielectric layer 138 may also be implemented as a conformal layer over the first dielectric layer 132. The second dielectric layer 138 may be 500 nanometers to 1.2 microns thick on horizontal surfaces of the first dielectric layer 132. The second dielectric layer 132 may include primarily silicon oxynitride, with a ratio of oxygen to nitrogen of 0.5 to 2.0. An effective bandgap energy of the second dielectric layer 138 is greater than an effective bandgap energy of the first dielectric layer 132. By way of example, the effective bandgap energy of the second dielectric layer 138 may be 5 eV to 7 eV. A refractive index of the second dielectric layer 138 is less than the refractive index of the first dielectric layer 132. By way of example, the refractive index of the second dielectric layer 138 may be 1.65 to 1.85. A dielectric constant of the second dielectric layer 138 is less than the dielectric constant of the first dielectric layer 132. By way of example, the dielectric constant of the second dielectric layer 138 may be 4.5 to 6.5.

The second dielectric layer 138 may be formed by a second PECVD process 140 which provides a carrier gas, labeled “CARRIER GAS”, a silicon reagent gas, labeled “SILICON REAGENT”, such as silane, an oxygen reagent gas, labeled “OXYGEN REAGENT”, such as nitrous oxide, a nitrogen reagent gas, labeled “NITROGEN REAGENT”, such as ammonia, and RF power, labeled “RF POWER”, to sustain a plasma. Flow rates of the oxygen reagent gas and the nitrogen reagent gas may be adjusted to provide the ratio of oxygen to nitrogen of 0.5 to 2.0 in the second dielectric layer 138.

Referring to FIG. 1F, a gap-fill layer 142 of an isolation dielectric layer stack 144 may be formed over the lower field reduction layer 134. The gap-fill layer 142 may include primarily silicon dioxide and may be formed by a high density plasma (HDP) process 146, using argon, oxygen, and silane, with RF power to sustain a plasma. The HDP process 146 may produce the gap-fill layer 142 with a desired low void density and low hydrogen content, to improve reliability of the microelectronic device 100. The HDP process 146 has a sputter action that may remove a portion of the second dielectric layer 138 over corners of the lower isolation element 128, so that a thickness of the second dielectric layer 138 over a corner of the lower isolation element 128 is thinner than the thickness of the second dielectric layer 138 over a middle of the lower isolation element 128. The thickness of the second dielectric layer 138 may be accordingly adjusted to compensate for this loss of dielectric material, so that the thickness of the second dielectric layer 138 over the corners of the lower isolation element 128 is at least 400 nanometers.

The gap-fill layer 142 has a refractive index that is less than the refractive index of the second dielectric layer 138, and has a dielectric constant that is less than the dielectric constant of the second dielectric layer 138. The gap-fill layer 142 may have a refractive index of 1.4 to 1.5, and may have a dielectric constant of 3.5 to 4.0, by way of example. Furthermore, the gap-fill layer 142 has an effective bandgap energy that is greater than the effective bandgap energy of the second dielectric layer 138. The gap-fill layer 142 may have an effective bandgap energy of 8 eV to 11 eV, by way of example.

The higher dielectric constant of the first dielectric layer 132 may advantageously reduce an electric field at corners of the lower isolation element 128, compared to having the gap-fill layer 142 directly contact the lower isolation element 128. The lower effective bandgap energy of the first dielectric layer 132 compared to the second dielectric layer 138, and the lower effective bandgap energy of the second dielectric layer 138 compared to the gap-fill layer 142 may provide a first valence band well at an interface between the first dielectric layer 132 and the second dielectric layer 138, and provide a second valence band well at an interface between the second dielectric layer 138 and the gap-fill layer 142, which may advantageously enable mobile charge that is produced by an electric field of a first polarity at the corners of the lower isolation element 128 to laterally disperse and dissipate, reducing a risk of dielectric breakdown. Similarly, the configuration of effective bandgap energies may provide a first conduction band well at the interface between the first dielectric layer 132 and the second dielectric layer 138, and provide a second conduction band well at the interface between the second dielectric layer 138 and the gap-fill layer 142, which may advantageously enable mobile charge that is produced by an electric field of a second polarity at the corners of the lower isolation element 128 to laterally disperse and dissipate, reducing the risk of dielectric breakdown. Tests performed on devices having lower isolation elements implemented as lower windings have shown that the values of refractive index, dielectric constant, effective bandgap energy, and thickness disclosed in this example provides greater than 10 kilovolts of maximum surge isolation voltage (VIOSM) as evaluated per International Electrotechnical Commission (IEC) standard IEC 61000-4-5, and provides greater than 7 kilovolts electrostatic discharge (ESD) breakdown as evaluated per IEC standard IEC 61000-4-2.

Referring to FIG. 1G, a buffer layer 148 of the isolation dielectric layer stack 144 is formed over the gap-fill layer 142. The buffer layer 148 may include primarily silicon dioxide and may be formed by a PECVD process 150 using tetraethoxysilane (TEOS), also referred to as tetraethyl orthosilicate, and oxygen, in a carrier gas, labeled “CARRIER GAS,” such as nitrogen, and RF power, labeled “RF POWER,” to sustain a plasma. The buffer layer 148 is sufficiently thick to extend above the gap-fill layer 142 across the microelectronic device 100. By way of example, the buffer layer 148 may be thicker than a combined thickness of the lower isolation element 128 and the gap-fill layer 142.

Referring to FIG. 1H, the buffer layer 148 and the gap-fill layer 142 are planarized. The buffer layer 148 and the gap-fill layer 142 may be planarized by an oxide CMP process, as indicated in FIG. 1H by the CMP Pad. Alternatively, the buffer layer 148 and the gap-fill layer 142 may be planarized by a resist etchback process, not specifically shown. Planarization of the buffer layer 148 and the gap-fill layer 142 may remove a portion of the gap-fill layer 142, as indicated in FIG. 1H. Alternatively, the buffer layer 148 may be planarized to a level above the gap-fill layer 142, leaving the gap-fill layer 142 intact.

Referring to FIG. 1I, the microelectronic device 100 may include a lower bond pad 152 that is electrically connected to the lower isolation element 128 through a member of the first interconnects 114 and instances of the vias 118. The lower bond pad 152 may be formed concurrently with the second interconnects 126.

Additional sublayers 154 of the isolation dielectric layer stack 144 are formed over the planarized buffer layer 148 and the gap-fill layer 142. The additional sublayers 154 may be formed as one or more sublayers of silicon dioxide. Sublayers of silicon nitride or silicon oxynitride may be formed in the additional sublayers 154 to provide etch stops, as described in U.S. patent application Ser. No. 17/958,040 (Texas Instruments docket number T92886US01, titled “SINGLE DIE REINFORCED GALVANIC ISOLATION DEVICE”, by West, et al.), Filed Sep. 30, 2022, and incorporated herein by reference. The additional sublayers 154 may be formed by one or more PECVD processes, by way of example. The isolation dielectric layer stack 144 may be 12 to 24 microns thick, by way of example.

An upper field reduction layer 156 may be formed over the isolation dielectric layer stack 144. The upper field reduction layer 156 may include a silicon oxynitride sublayer 158 over the isolation dielectric layer stack 144, and a silicon nitride sublayer 160 over the silicon oxynitride sublayer 158. Other sublayer structures and compositions for the upper field reduction layer 156 are within the scope of this example.

An upper isolation element 162 of the isolation component 130 is formed over the isolation dielectric layer stack 144, on the upper field reduction layer 156, if present. The upper isolation element 162 may be manifested as an upper winding 162 formed in top interconnects 164 of the microelectronic device 100. The microelectronic device 100 may include additional layers of dielectric material, such as a protective overcoat, not specifically shown, over the upper isolation element 162. The microelectronic device 100 may include an upper bond pad 166 above the isolation dielectric layer stack 144, electrically connected to the upper isolation element 162.

During operation of the microelectronic device 100, the upper isolation element 162 may be operated at a high potential difference with respect to the lower isolation element 128, for example at a potential difference of 450 volts root mean square (rms) to 1500 volts rms. The lower field reduction layer 134 may advantageously reduce an electric field at corners of the lower isolation element 128, and may dissipate charge that may be generated at the corners of the lower isolation element 128, thus providing improved reliability for the microelectronic device 100. The upper field reduction layer 156 may provide a similar advantage in reducing electric fields at corners of the upper isolation element 162.

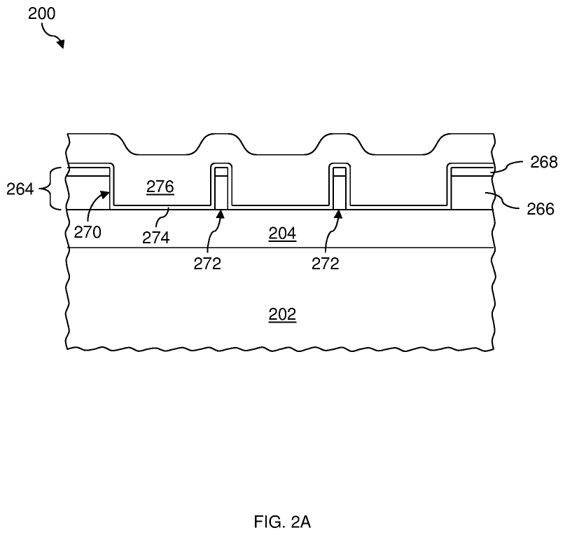

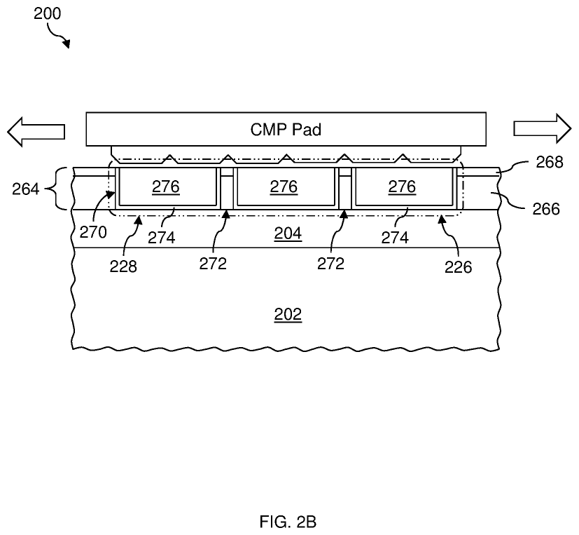

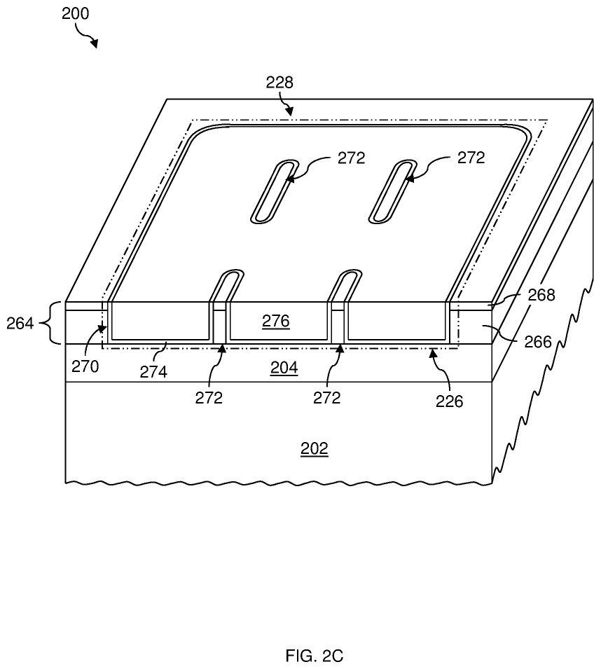

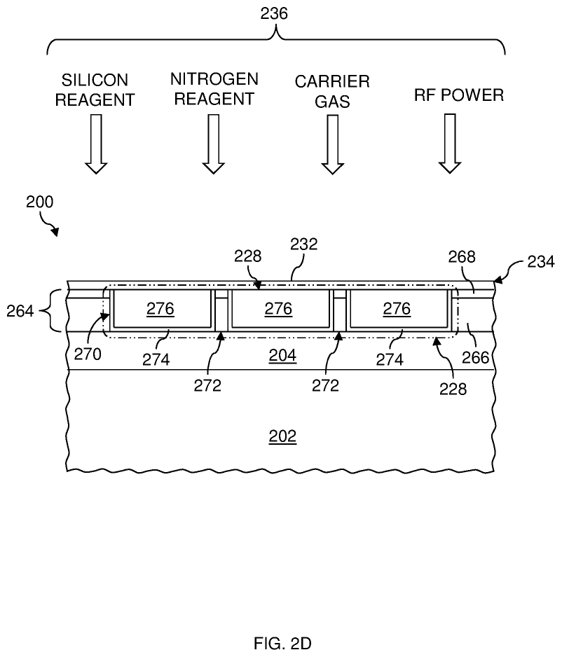

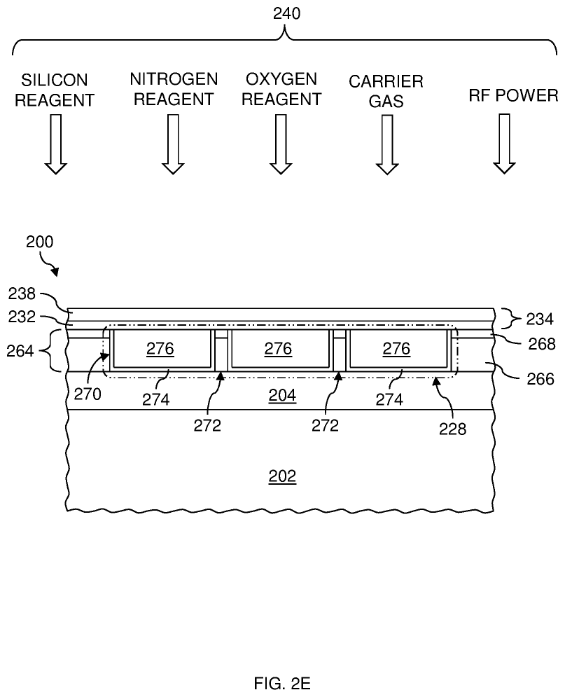

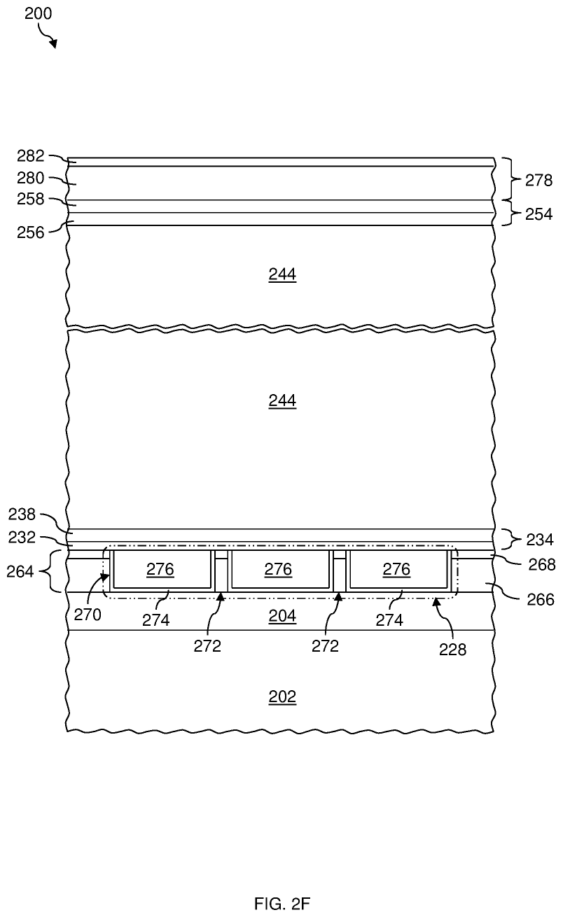

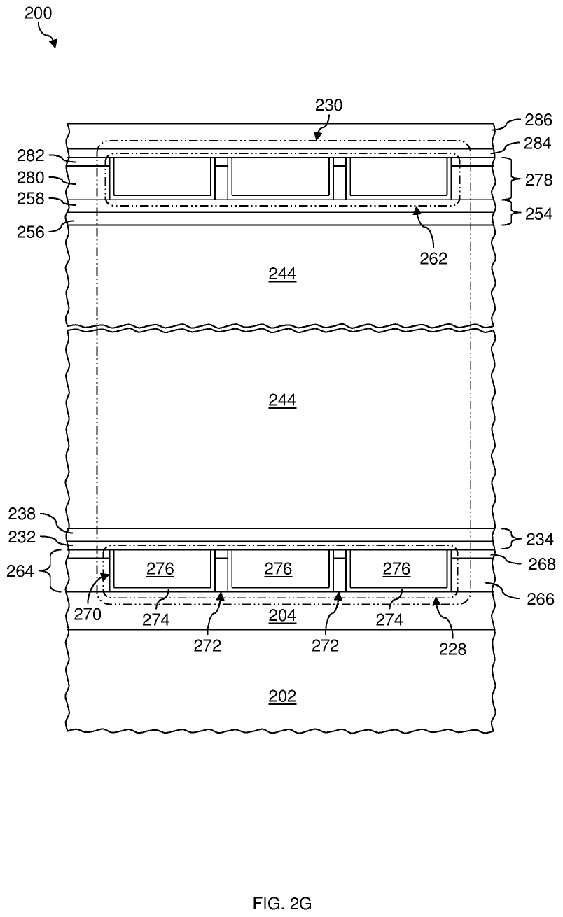

FIG. 2A through FIG. 2G are cross sections of another example microelectronic device having a lower field reduction layer, depicted in stages of another example method of formation. Referring to FIG. 2A, the microelectronic device 200 is formed on a substrate 202 which is electrically conductive. The substrate 202 may be implemented as a silicon wafer, a ceramic substrate with a conductive coating, or other electrically conductive substrate.

A PMD layer 204 is formed over the substrate 202. The PMD layer 204 in this example may include primarily silicon dioxide formed by a thermal oxidation process, or may include one or more sublayers of dielectric material, formed by one or more LPCVD and PECVD processes.

A lower intra-metal dielectric (IMD) layer 264 is formed over the PMD layer 204. The lower IMD layer 264 may include a main sublayer 266 of silicon dioxide and a CMP stop sublayer 268 of silicon nitride or silicon carbide. The lower IMD layer 264 may be formed by LPCVD or PECVD processes.

A capacitor trench 270 is formed in the lower IMD layer 264. The capacitor trench 270 may extend to the PMD layer 204, as depicted in FIG. 2A, may extend partway into the PMD layer 204, or may extend only partway into the lower IMD layer 264. The capacitor trench 270 may be formed by a sequence of RIE processes. The capacitor trench 270 may include slots 272 of the lower IMD layer 264, to reduce dishing during a subsequent copper CMP process.

A barrier liner 274 is formed on the lower IMD layer 264, extending into the capacitor trench 270. The barrier liner 274 may include tantalum and tantalum nitride, or may include titanium and titanium nitride. The barrier liner 274 may be formed by a PVD process, followed by an ALD process or a reactive sputter process.

A copper fill layer 276 is formed on the barrier liner 274, filling the capacitor trench 270 and extending over the lower IMD layer 264. The copper fill layer 276 may be formed by forming a copper seed layer on the barrier liner 274 by a PVD process, followed by a copper electroplating process.

Referring to FIG. 2B, the copper fill layer 276 and the barrier liner 274 are removed from over the lower IMD layer 264, leaving the barrier liner 274 and the copper fill layer 276 in the capacitor trench 270 to form a lower isolation element 228. The lower isolation element 228 is thus formed by a copper damascene process. In this example, the lower isolation element 228 is manifested as a lower capacitor plate 228. The copper fill layer 276 and the barrier liner 274 may be removed from over the lower IMD layer 264 by a copper CMP process using a CMP pad, as indicated in FIG. 2B. The CMP stop sublayer 268 of the lower IMD layer 264 may facilitate forming the lower isolation element 228 to have a desired thickness. The slots 272 of the lower IMD layer 264 may reduce dishing by the copper CMP process, further facilitating forming the lower isolation element 228 to have the desired thickness. The lower isolation element 228 may be a member of first interconnects 226 of the microelectronic device 200.

FIG. 2C depicts the microelectronic device 200 after the copper fill layer 276 and the barrier liner 274 are removed from over the lower IMD layer 264. The copper fill layer 276 and the barrier liner 274 are both contiguous in the lower isolation element 228. The copper fill layer 276 and the barrier liner 274 may extend laterally to components or bond pads, not specifically shown. The lower isolation element 228 has a copper damascene configuration, in which the lower isolation element 228 includes a copper fill layer 276 on a barrier liner 274 in a trench 270 in a dielectric layer.

Referring to FIG. 2D, a first dielectric layer 232 of a lower field reduction layer 234 is formed over the lower isolation element 228. The first dielectric layer 232 may include primarily silicon nitride. The first dielectric layer 232 may be 100 nanometers to 500 nanometers thick. The first dielectric layer 232 of this example may have a refractive index of 2.15 to 2.20, a dielectric constant of 7.0 to 10.0, and an effective bandgap energy of 3.0 eV to 3.7 eV, by way of example.

The first dielectric layer 232 may be formed by a first PECVD process 236 which provides a carrier gas, labeled “CARRIER GAS”, a silicon reagent gas, labeled “SILICON REAGENT”, a nitrogen reagent gas, labeled “NITROGEN REAGENT”, and RF power, labeled “RF POWER”. Flow rates of the silicon reagent gas and the nitrogen reagent gas may be adjusted to attain a desired refractive index of the first dielectric layer 232. The refractive index of 2.15 to 2.20 and dielectric constant of 7.0 to 10.0 may be attained in the first PECVD process 236 by providing a silane flow rate of 900 standard cubic centimeters per minute (sccm) to 1200 sccm, an ammonia flow rate of 200 sccm to 300 sccm, and a carrier gas flow rate of 10,000 sccm to 12,000 sccm, at a pressure of 3 torr to 4 torr and an RF power of 900 watts to 1000 watts, for a 300 millimeter wafer. Other process conditions to attain the refractive index of 2.15 to 2.20 are within the scope of this example.

The CMP stop sublayer 268 may have properties similar to the first dielectric layer 232, including a dielectric constant of 7.0 to 10.0. Thus, upper corners of the lower isolation element 228 are surrounded by dielectric material having a dielectric constant of 7.0 to 10.0.

Referring to FIG. 2E, a second dielectric layer 238 of the lower field reduction layer 234 is formed over the first dielectric layer 232. The second dielectric layer 238 may be 500 nanometers to 1.2 microns thick. The second dielectric layer 238 may include primarily silicon oxynitride, with a ratio of oxygen to nitrogen of 0.5 to 2.0. An effective bandgap energy of the second dielectric layer 238 is greater than an effective bandgap energy of the first dielectric layer 232. By way of example, the effective bandgap energy of the second dielectric layer 238 may be 4.5 eV to 7.0 eV. A refractive index of the second dielectric layer 238 is less than the refractive index of the first dielectric layer 232. By way of example, the refractive index of the second dielectric layer 238 may be 1.65 to 1.95. A dielectric constant of the second dielectric layer 238 is less than the dielectric constant of the first dielectric layer 232. By way of example, the dielectric constant of the second dielectric layer 238 may be 4.5 to 6.5.

The second dielectric layer 238 may be formed by a second PECVD process 240 which provides a carrier gas, labeled “CARRIER GAS”, a silicon reagent gas, labeled “SILICON REAGENT”, an oxygen reagent gas, labeled “OXYGEN REAGENT”, a nitrogen reagent gas, labeled “NITROGEN REAGENT”, and RF power, labeled “RF POWER”. Flow rates of the oxygen reagent gas and the nitrogen reagent gas may be adjusted to provide the ratio of oxygen to nitrogen of 0.5 to 2.0 in the second dielectric layer 238.

Referring to FIG. 2F, an isolation dielectric layer stack 244 is formed over the lower field reduction layer 234. The isolation dielectric layer stack 244 may be formed as one or more sublayers of silicon dioxide, optionally with sublayers of silicon nitride or silicon oxynitride. The isolation dielectric layer stack 244 may be formed by one or more PECVD processes. The isolation dielectric layer stack 244 may be 12 to 24 microns thick.

The isolation dielectric layer stack 244 adjacent to the lower field reduction layer 234 has a refractive index that is less than the refractive index of the second dielectric layer 238, and has a dielectric constant that is less than the dielectric constant of the second dielectric layer 238. The isolation dielectric layer stack 244 adjacent to the lower field reduction layer 234 may have a refractive index of 1.4 to 1.5, and may have a dielectric constant of 3.5 to 4.0, by way of example. Furthermore, the isolation dielectric layer stack 244 adjacent to the lower field reduction layer 234 has an effective bandgap energy that is greater than the effective bandgap energy of the second dielectric layer 238. The isolation dielectric layer stack 244 adjacent to the lower field reduction layer 234 may have an effective bandgap energy of 8 eV to 11 eV, by way of example.

The higher dielectric constant of the first dielectric layer 232 coupled with the CMP stop sublayer 268 may advantageously reduce an electric field at corners of the lower isolation element 228, compared to having the isolation dielectric layer stack 244 directly contact the lower isolation element 228. The configuration of the effective bandgap energies of the first dielectric layer 232, the second dielectric layer 238, and the isolation dielectric layer stack 244 adjacent to the lower field reduction layer 234 may provide the advantage disclosed in reference to the microelectronic device 100 of FIG. 1I. Tests performed on devices having lower isolation elements implemented as capacitor plates have shown that the values of refractive index, dielectric constant, effective bandgap energy, and thickness disclosed in this example provides greater than 14 kilovolts of maximum surge isolation voltage (VIOSM) as evaluated per IEC 61000-4-5, and provides greater than 6 kilovolts ESD breakdown as evaluated per IEC 61000-4-2.

An upper field reduction layer 254 may be formed over the isolation dielectric layer stack 244. The upper field reduction layer 254 may include a silicon oxynitride sublayer 256 over the isolation dielectric layer stack 244, and a silicon nitride sublayer 258 over the silicon oxynitride sublayer 256. Other sublayer structures and compositions for the upper field reduction layer 254 are within the scope of this example.

An upper IMD layer 278 is formed over the isolation dielectric layer stack 244, on the upper field reduction layer 254, if present. The upper IMD layer 278 may include a main sublayer 280 of silicon dioxide and a CMP stop sublayer 282 of silicon nitride or silicon carbide, similar to the lower IMD layer 264. The upper IMD layer 278 may be formed by LPCVD or PECVD processes, similar to the lower IMD layer 264.

Referring to FIG. 2G, an upper isolation element 262 of the isolation component 230 is formed in the upper IMD layer 278, over the upper field reduction layer 254, if present. The upper isolation element 262 may be manifested as an upper capacitor plate 262 formed in by a copper damascene process, as disclosed in reference to the lower isolation element 228. The microelectronic device 200 may include additional layers of dielectric material, such as a cap layer 284 of silicon nitride or silicon carbonitride, on the upper isolation element 262, and a protective overcoat 286 of one or more sublayers of silicon oxynitride, silicon dioxide, or polyimide. The microelectronic device 200 may further include additional interconnects and bond pads, also not specifically shown.

During operation of the microelectronic device 200, the upper isolation element 262 may be operated at a high potential difference with respect to the lower isolation element 228, for example at a potential difference of 450 volts to 1500 volts. The lower field reduction layer 234, coupled with the CMP stop sublayer 268 may advantageously reduce an electric field at corners of the lower isolation element 228, and may dissipate charge that may be generated at the corners of the lower isolation element 228, thus providing improved reliability for the microelectronic device 200. The upper field reduction layer 254 may provide a similar advantage in reducing electric fields at corners of the upper isolation element 262.

Various features of the examples disclosed herein may be combined in other manifestations of example microelectronic devices. For example, the structures of FIG. 1I or FIG. 2G may have lower isolation elements 128 or 228 that are manifested as lower windings of isolation transformers or magnetic couplers. The structures of FIG. 1I or FIG. 2G may have lower isolation elements 128 or 228 that are manifested as lower capacitor plates of isolation capacitors. The structures of FIG. 1I or FIG. 2G may have lower isolation elements 128 or 228 that have etched aluminum configurations. The structures of FIG. 1I or FIG. 2G may have lower isolation elements 128 or 228 that have copper damascene configurations.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a substrate;
a lower isolation element above the substrate, the lower isolation element being electrically conductive;
a lower field reduction layer over the lower isolation element:
an isolation dielectric layer stack over the lower field reduction layer; and
an upper isolation element over the isolation dielectric layer stack, the upper isolation element being electrically conductive; wherein:
the lower field reduction layer includes a first dielectric layer adjacent to the lower isolation element;
the first dielectric layer has a first dielectric constant greater than a dielectric constant of the isolation dielectric layer stack adjacent to the lower field reduction layer;
the lower field reduction layer includes a second dielectric layer between the first dielectric layer and the isolation dielectric layer stack; and
the second dielectric layer has a second dielectric constant greater than the dielectric constant of the isolation dielectric layer stack adjacent to the lower field reduction layer and less than the first dielectric constant.

2. The microelectronic device of claim 1, wherein:
the isolation dielectric layer stack adjacent to the lower isolation element includes primarily silicon dioxide;
the first dielectric layer includes primarily silicon nitride; and
the second dielectric layer includes primarily silicon oxynitride.

3. The microelectronic device of claim 2, wherein:
the silicon nitride has a refractive index of 2.00 to 2.20; and
the silicon oxynitride has a ratio of oxygen to nitrogen of 0.5 to 2.0.

4. The microelectronic device of claim 2, wherein the silicon nitride has a refractive index of 2.03 to 2.07; and has an effective band gap energy of 4.5 electron-volts (eV) to 5.3 eV.

5. The microelectronic device of claim 4, wherein the lower isolation element is a lower winding of an isolation transformer.

6. The microelectronic device of claim 2, wherein the silicon nitride has a refractive index of 2.15 to 2.20; and has an effective band gap energy of 3.0 eV to 3.7 eV.

7. The microelectronic device of claim 6, wherein the lower isolation element is a lower capacitor plate of an isolation capacitor.

8. The microelectronic device of claim 1, wherein:
the first dielectric layer has a thickness of 100 nanometers to 500 nanometers; and
the second dielectric layer has a thickness of 500 nanometers to 1.2 microns.

9. The microelectronic device of claim 1, wherein a thickness of the second dielectric layer over a corner of the lower isolation element is thinner than the thickness of the second dielectric layer over a middle of the lower isolation element.

10. The microelectronic device of claim 1, wherein:
the first dielectric layer has an effective band gap energy less than an effective band gap energy of the second dielectric layer; and
the effective band gap energy of the second dielectric layer is less than an effective band gap energy of the isolation dielectric layer stack adjacent to the lower field reduction layer.

11. A method of forming a microelectronic device, comprising:
forming a lower isolation element above a substrate, the lower isolation element being electrically conductive;
forming a first dielectric layer of a lower field reduction layer over the lower isolation element:
forming a second dielectric layer of the lower field reduction layer over the first dielectric layer;
forming an isolation dielectric layer stack over the second dielectric layer; and
forming an upper isolation element over the lower isolation element, the upper isolation element being electrically conductive; wherein:
the first dielectric layer has a first dielectric constant greater than a dielectric constant of the isolation dielectric layer stack adjacent to the lower field reduction layer; and
the second dielectric layer has a second dielectric constant greater than the dielectric constant of the isolation dielectric layer stack adjacent to the lower field reduction layer and less than the first dielectric constant.

12. The method of claim 11, wherein:
forming the first dielectric layer includes forming silicon nitride by a plasma enhanced chemical vapor deposition (PECVD) process;
forming the second dielectric layer includes forming silicon oxynitride by a PECVD process; and
forming the isolation dielectric layer stack includes forming silicon dioxide adjacent to the second dielectric layer.

13. The method of claim 12, wherein:
the silicon nitride has a refractive index of 2.00 to 2.20; and
the silicon oxynitride has a ratio of oxygen to nitrogen of 0.5 to 2.0.

14. The method of claim 12, wherein the silicon nitride has a refractive index of 2.03 to 2.07; and has an effective band gap energy of 4.5 electron-volts (eV) to 5.3 eV.

15. The method of claim 14, wherein forming the silicon nitride is performed by:
providing a silane flow rate of 900 standard cubic centimeters per minute (sccm) to 1200 sccm;
providing an ammonia flow rate of 200 sccm to 300 sccm,
providing a carrier gas flow rate of 10,000 sccm to 12,000 sccm;
maintaining a pressure of 4 torr to 6 torr; and
providing a radio frequency (RF) power of 900 watts to 1200 watts.

16. The method of claim 12, wherein the silicon nitride has a refractive index of 2.15 to 2.20; and has an effective band gap energy of 3.0 eV to 3.7 eV.

17. The method of claim 16, wherein forming the silicon nitride is performed by:
providing a silane flow rate of 900 sccm to 1200 sccm;
providing an ammonia flow rate of 200 sccm to 300 sccm,
providing a carrier gas flow rate of 10,000 sccm to 12,000 sccm;
maintaining a pressure of 3 torr to 4 torr; and
providing an RF power of 900 watts to 1200 watts.

18. The method of claim 11, wherein:
the first dielectric layer has a thickness of 100 nanometers to 500 nanometers; and
the second dielectric layer has a thickness of 500 nanometers to 1.2 microns.

19. The method of claim 11, wherein forming the isolation dielectric layer stack removes a portion of the second dielectric layer over a corner of the lower isolation element, so that a thickness of the second dielectric layer over a corner of the lower isolation element is thinner than the thickness of the second dielectric layer over a middle of the lower isolation element.

20. The method of claim 11, wherein:
the first dielectric layer has an effective band gap energy less than an effective band gap energy of the second dielectric layer; and
the effective band gap energy of the second dielectric layer is less than an effective band gap energy of the isolation dielectric layer stack adjacent to the lower field reduction layer.
